(19) United States
(12) Patent Application Publication
(10) Pub. No.: US 2008/0160455 A1
(43) Pub. Date: Jul. 3, 2008

(54) Exposure Method, Method for Forming Projecting and Recessed Pattern, and Method for Manufacturing Optical Element

(75) Inventors: Yoshihito Hodosawa, Shizuoka (JP); Chikara Egami, Shizuoka (JP)

Correspondence Address: SUGHRUE MION, PLLC, 2100 PENNSYLVANIA AVENUE, N.W., SUITE 800, WASHINGTON, DC, 20037, US

(73) Assignee: FUJIFLIM Corporation, Minato-ku (JP)

(21) Appl. No.: 11/795,813

(22) PCT Filed: Jan. 24, 2006
(86) PCT No.: PCT/JP06/01381

§ 371 Date: Jul. 23, 2007

(30) Foreign Application Priority Data
Jan. 24, 2005 (JP) 2005-015799

(51) Int. Cl. G03F 7/20; G03F 7/26

(52) U.S. Cl. 430/321; 430/322

(57) ABSTRACT

An exposure pattern having a line width of submicron size is simply formed by using an inexpensive and stable solid state laser or a gas laser as an exposure light source, and by using a photoresist for g-line or i-line. The exposure is performed by locally controlling a reaction time constant of the photosensitive material with beaming the laser beam on a predetermined portion of a layer of the photosensitive material having a predetermined thickness formed on the surface of a substrate W, with beam intensity and scanning rate of the laser beam being controlled.

### TECHNICAL FIELD

The present invention relates to an exposure method, a method for forming a projecting and recessed pattern, and a method for manufacturing an optical element, and more particularly to an exposure method suitable for manufacturing an optical element having a projecting and recessed pattern used for applications, such as an antireflection film and other members having a projecting and recessed pattern, a method for forming the projecting and recessed pattern by using the exposure method, and a method for manufacturing the optical element.

### BACKGROUND ART

Conventionally, photofabrication using a photosensitive photoresist has been applied to various fields. For example, a technical field in which a relatively low precision is required, includes an application to a printed board, and a technical field in which a relatively high precision is required, includes an application to a semiconductor, such as LSI.

As a light source (beam source) used for the photofabrication, there have been used a mercury lamp, a laser beam, and a charged particle beam such as an electron beam. As a patterning method, there have also been used a mask exposure method by which an exposure pattern is formed by using a mask pattern such as a photomask, and a direct drawing method by which a beam is scanned in a pattern shape so as to make an exposure pattern formed.

Among the patterning methods, the direct drawing method performed by using a laser beam has a large degree of freedom in patterning and is suitable for a form of production of many kinds in small quantity. For this reason, the direct drawing method is applied for manufacturing of a photomask (forming an exposure pattern) for forming semiconductor circuits and the like (for example, see Japanese Patent Laid-Open No. 2004-144885).

The proposal made in Japanese Patent Laid-Open No. 2004-144885 relates to a method for correcting a laser beam, in which exposure processing for a unit pattern is repeated to form multiple units, and in which a plurality of laser beams are used and factors causing dimensional fluctuation in each beam are corrected.

In recent years, there has been a strong demand for making the line width of semiconductor circuits very narrow in accordance with miniaturization of a design rule of semiconductor circuits. In order to cope with this demand, there has also been a strong demand for making the beam width of laser beam very narrow.

However, the beam width of a laser beam corresponds to an Airy disk of the laser beam, and hence, can be converged only into a level equivalent to the wave length of the laser light source because of the diffraction limit. FIG. 7 is a conceptual figure explaining this phenomenon.

A laser beam having a light flux diameter of 2n is condensed by a lens 2, but the spot size is restricted by diffraction to be a primary Airy disk 3. However, the spot size for photoresist exposure is expanded up to a secondary Airy disk 4. Therefore, in the present situation, the requirement to reduce the line width to 1 μm or less can not be satisfied by using ordinary laser light sources (semiconductor laser, CO₂ gas laser, YAG laser and the like).

On the other hand, in forming a submicron pattern, drawing is performed by using an ultraviolet laser light source such as ArF laser, KrF laser, and a charged particle beam such as an electron beam. However, the ultraviolet laser light source has disadvantages that it is expensive and management to maintain its stability is difficult, and also that an extremely expensive resist must be used.

Further, the electron beam exposure device has disadvantages that the need for a vacuum chamber, an electron beam gun, an electron beam deflector and the like makes the device complicated and expensive, and also that the device has a small drawing area and a slow drawing speed.

Alternatively, there have been proposed specific methods, such as a method in which expansion of the beam is suppressed by filling a specific liquid between the focusing lens and the photoresist, so as to make exposure performed, and a method in which a microstructure is formed by using a near-field light. However, these specific methods are also not simple, and do not make it possible to form a microstructure simply and inexpensively.

The present invention has been made in view of the above described circumstances. An object of the invention is to provide an exposure method which makes it possible to simply form an exposure pattern having a line width of submicron size by using, as an exposure light source, a solid state laser (YAG laser and the like) and a gas laser (Ar⁺ laser and the like) which are stable and inexpensive, and by using a conventionally used photoresist for g-line or i-line, and also to provide by using the exposure method, a method for forming a projecting and recessed pattern, and a method for manufacturing an optical element.

### DISCLOSURE OF THE INVENTION

In order to achieve the above described object, according to the present invention, there is provided an exposure method characterized in that exposure is performed while a reaction time constant of a photosensitive material having a predetermined thickness formed on the surface of a substrate is locally controlled by irradiating a laser beam on a layer of the photosensitive material, with the beam intensity and the beam scanning rate of the laser beam being controlled.

According to the present invention, exposure is performed to locally control a reaction time constant of a photosensitive material by irradiating a laser beam on a layer of the photosensitive material, with the beam intensity and the beam scanning rate of the laser beam being controlled, as a result of which it is possible to perform drawing with a line width thinner than the Airy disk of the exposure beam. Thereby, it is possible to easily form an exposure pattern having a line width of submicron size by using, as an exposure light source, a solid state laser (YAG laser and the like) and a gas laser (Ar⁺ laser and the like) which are inexpensive and stable, and by using a conventionally used photoresist for g-line or i-line.

That is, according to the present invention, there is provided a method for forming an exposure pattern having a line width of submicron size by utilizing a nonlinear characteristic not in an ordinary steady state but in a transient response state in exposing a photosensitive material such as a photoresist. The detailed principle of the method will be described below. Further, according to the present invention, there is provided an exposure method characterized in that exposure is performed while a reaction time constant of a photosensitive material having a predetermined thickness formed on the surface of a substrate is locally controlled by irradiating a laser beam in pulse state on a layer of the photosensitive material, with the beam intensity and the pulse width of the laser beam being controlled.

According to the present invention, exposure is performed to locally control a reaction time constant of a photosensitive material by irradiating a laser beam in pulse state on a layer of the photosensitive material with the beam intensity and the pulse width of the laser beam being controlled, as a result of which it is possible to perform drawing of a hole and/or a post smaller in size than the Airy disk of the exposure beam. Thereby, it is possible to simply form an exposure pattern having a line width of submicron size, or of a hole and/or a post of submicron size, by using, as an exposure light source, a solid state laser (YAG laser and the like) and a gas laser (Ar⁺ laser and the like) which are inexpensive and stable, and by using a conventionally used photoresist for g-line or i-line.

In the present invention, the above described laser beam is preferably a temporally and spatially coherent light. When the beam is temporally and spatially coherent light, a further advantage according to the present invention can be obtained.

Further, according to the present invention, there is provided a method for forming a projecting and recessed pattern, characterized in that the method comprises the steps of: forming a layer of a photosensitive material having a predetermined thickness on the surface of a substrate; performing exposure to locally control a reaction time constant of the photosensitive material by controlling beam intensity and beam scanning rate of the laser beam, while beaming a laser beam on the layer of the photosensitive material; and applying a developing processing to the layer of the photosensitive material after exposure, to form a plurality of fine projecting and recessed patterns on the layer of the photosensitive material.

According to the present invention, the above described exposure method is applied to form the projecting and recessed pattern, so that the projecting and recessed pattern with high precision can be inexpensively and stably manufactured.

In the present invention, the height of the projecting and recessed pattern is preferably set to 0.1 to 100 μm. When the height of the projecting and recessed pattern is set to this range, a required optical characteristic such as anti-reflection function can be made to be preferred, and advantages in terms of production can also be obtained.

Further, in the present invention, the substrate is preferably a columnar body or a cylindrical body. When the substrate is a columnar body or a cylindrical body, as will be described below, roll processing can be employed in the case where the substrate having the projecting and recessed pattern is used to further duplicate an optical element and the like having the projecting and recessed pattern, as a result of which productivity can be significantly improved and many advantages can also be obtained in terms of cost reduction and the like.

Further, according to the present invention, there is provided a method for manufacturing an optical element by using the above described method for forming the projecting and recessed pattern, characterized in that the method comprises the steps of: producing a stamper to which the plurality of projecting and recessed patterns are transferred by using the plurality of projecting and recessed patterns formed on the surface of the substrate; and duplicating a plurality of projecting and recessed patterns substantially the same in shape as the plurality of projecting and recessed patterns, on the surface of a resin material by molding using the stamper.

According to the present invention, an optical element can be further duplicated by using the substrate which has already been produced. That is, a stamper is produced, and a plurality of fine projecting and recessed patterns are formed on the surface of a resin material by molding using the stamper. As a result, productivity can be significantly improved, and many advantages can also be obtained in terms of cost reduction and the like.

Noted that the stamper generally represents a flat plate body to which a surface shape of a substrate (mother) is transferred, but here, those having a curved surface such as a columnar body or a cylindrical body may also be used as the stamper.

As described above, according to the exposure method of the present invention, it is possible to perform drawing with a line width, or a hole and/or a post, which are thinner than the Airy disk of the exposure beam.

Further, according to the method for forming a projecting and recessed pattern of the present invention, the above described exposure method is applied to form the projecting and recessed pattern, so that the projecting and recessed pattern with high precision can be inexpensively and stably produced.

Further, according to the method for manufacturing an optical element of the present invention, a stamper is produced, and a plurality of fine projecting and recessed patterns are formed on the surface of a resin material by molding using the stamper. Thereby, productivity can be significantly improved and many advantages can also be obtained in terms of cost reduction and the like.

### BRIEF DESCRIPTION OF THE DRAWINGS

FIG. 1 is a figure showing a configuration of an exposure device used for an exposure method, a method for forming a projecting and recessed pattern, and a method for manufacturing an optical element, according to the present invention;

FIG. 2 is a conceptual figure showing a mode in which the surface of a substrate is drawn by a condensed laser beam;

FIG. 3 is a graph showing an absorbance characteristic of a photoresist in each wave length;

FIG. 4 is a conceptual figure showing an energy diagram of the photoresist;

FIG. 5A is a schematic sectional view showing a step of processing a substrate;

FIG. 5B is a schematic sectional view showing a step of processing the substrate;

FIG. 5C is a schematic sectional view showing a step of processing the substrate;

FIG. 6A is a conceptual figure explaining a step of producing a stamper;

FIG. 6B is a conceptual figure explaining a step of producing a stamper;

FIG. 6C is a conceptual figure explaining a step of producing a stamper;

FIG. 6D is a conceptual figure explaining a step of producing a stamper;

FIG. 6E is a conceptual figure explaining a step of producing a stamper;

FIG. 7 is a conceptual figure explaining a profile of a laser beam;

FIG. 8A is a conceptual figure explaining another step of producing a stamper;

FIG. 8B is a conceptual figure explaining another step of producing a stamper;

FIG. 8C is a conceptual figure explaining another step of producing a stamper;

FIG. 8D is a conceptual figure explaining another step of producing the stamper; and

FIG. 8E is a conceptual figure explaining another step of producing a stamper.

### DESCRIPTION OF SYMBOLS

10 . . . Exposure device
12 . . . Exposure light source
14 . . . Substrate table
16 . . . Laser light source
18 . . . Collimator lens
20 . . . Base
22 . . . X-axis moving stage
24 . . . Y-axis moving stage
30 . . . Photoresist layer
40 . . . Conductive layer
42 . . . Nickel layer (reversed mother)
44 . . . Nickel layer (Ni mother)
46 . . . Nickel layer (stamper)
W . . . Specimen (substrate)

### BEST MODE FOR CARRYING OUT THE INVENTION

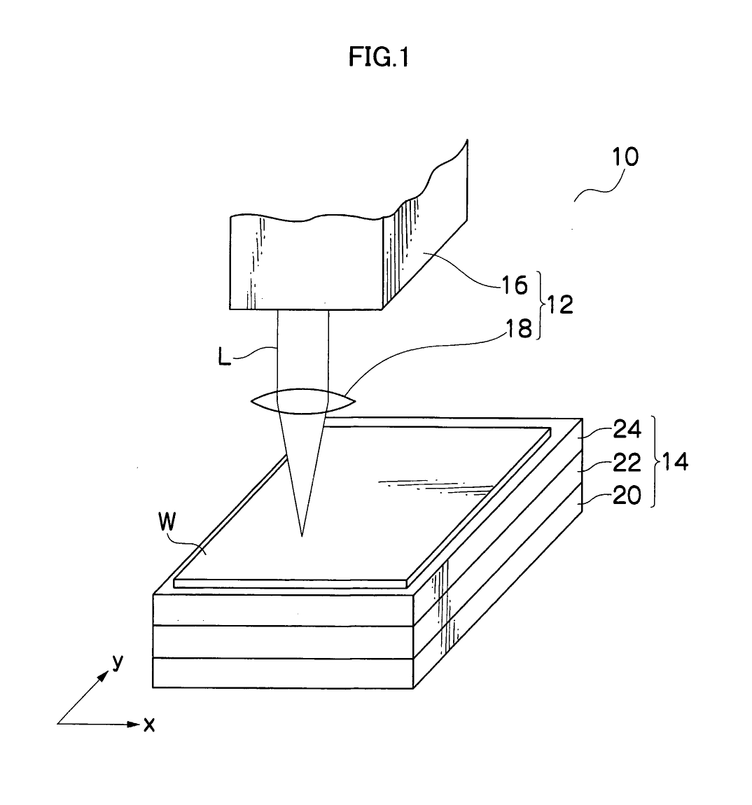

In the following, preferred embodiments of an exposure method, a method for forming a projecting and recessed pattern, and a method for manufacturing an optical element, according to the present invention, will be described with reference to the accompanying drawings. FIG. 1 shows an outline of an exposure device used for an exposure method, a method for forming a projecting and recessed pattern, and a method for manufacturing an optical element, according to the present invention.

An exposure device 10 in FIG. 1 comprises an exposure light source 12 and a substrate table 14, of which the exposure light source 12 comprises a laser light source 16 and a collimator lens 18. A laser beam L which is parallel light having a predetermined diameter of luminous flux emitted from the laser light source 16, is condensed by the collimator lens 18 and can be adjusted so as to be irradiated on the surface of a substrate W in a focal distance.

The substrate table 14 comprises a base 20, an X-axis moving stage 22, a Y-axis moving stage 24 and the like. The X-axis moving stage 22 can be relatively moved to the X-axis direction as shown in FIG. 1 by a driving device (not shown). Further, the Y-axis moving stage 24 can be relatively moved to the Y-axis direction as shown in FIG. 1 with respect to the X-axis moving stage 22 by a driving device (not shown).

On the upper surface of the Y-axis moving stage 24, a chuck (for example, an electrostatic chuck, not shown) for sucking the substrate W is provided so that the substrate W can be fixed.

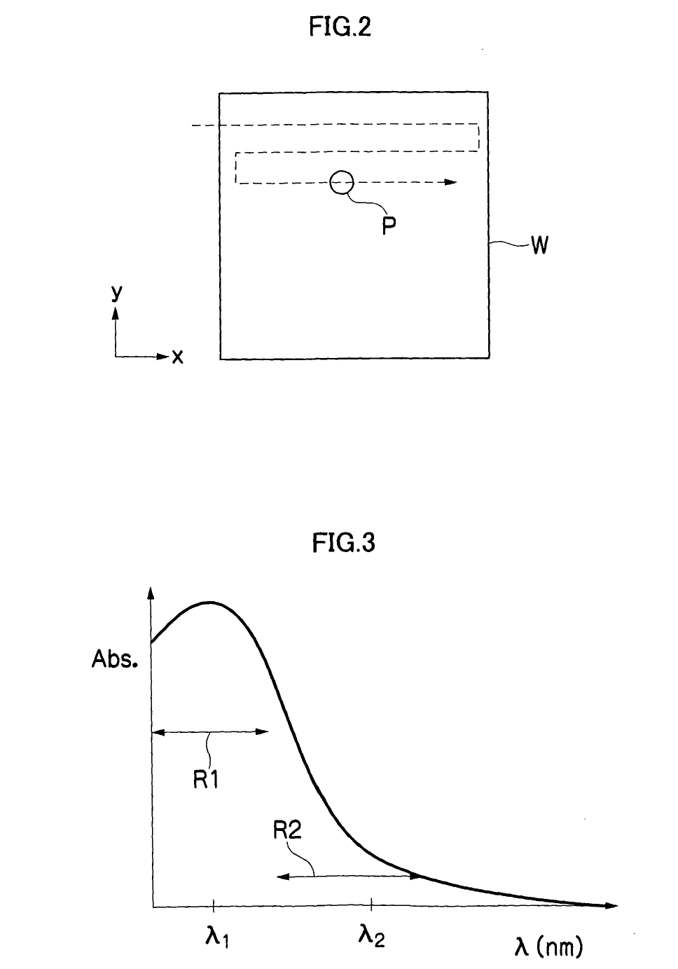

A photosensitive material (photoresist) formed on the surface of the substrate W is exposed by the exposure device 10 configured as described above. FIG. 2 is a conceptual figure (top view) showing a mode in which the surface of the substrate W is drawn by the condensed laser beam. In FIG. 2, a spot P of the laser beam at a focus position of the collimator lens 18 is scanned in the X-axis direction and in the Y-axis direction as shown by a broken line in the figure, and the X-axis moving stage 22 and the Y-axis moving stage 24 are driven so that almost the whole surface of the substrate W is exposed.

As the laser light source 16, a Nd:YAG laser can be used. The wavelength of the second harmonic wave (SHG) of the laser light source 16 is 532 nm. As the laser light source 16, an argon laser can be used in addition to the YAG laser. Noted that the other kind of laser light source may also be used, as long as the beam as the laser light source 16 is temporally and spatially coherent light. Further, when a stable laser light source with a short wavelength is obtained, the laser light source is preferably used.

The number of longitudinal modes of the exposure beam emitted from the laser light source 16 is preferably three or less. This is because the spontaneous transition probability as will be described below depends upon the number of longitudinal modes. Ideally, laser light whose exposure beam has the number of longitudinal mode of one (single longitudinal mode), is preferably used.

As the substrate W, a plate glass, a silicon wafer, a ceramic substrate and the like can be used. On the surface of the substrate W, a layer of photoresist as a photosensitive material is formed. As the photoresist, various kinds of known materials can be used. When a YAG laser or an argon ion laser is used as the laser light source 16, the conventionally used photoresist for g-line or i-line can be preferably used.

As such photoresist, for example, a photoresist made by Arch Corp. (product name: OIR-907) can be used. As a method for forming a layer of photoresist on the surface of the substrate W, various kinds of known methods such as, for example, various kinds of coating methods including a spin-coating method, a die coating method, a roll coating method, a dip coating method, a screen printing method and the like.

Next, the principle of the exposure method according to the present invention is described. In the present invention, a laser beam is irradiated on a layer of photoresist from the laser light source 16, while its beam intensity is controlled, and the moving speed (scanning rate) in the X-axis direction and the Y-axis direction of the substrate table 14 is controlled.

That is, exposure is performed to locally control a reaction time constant of the photoresist. This makes it possible to perform drawing with a line width thinner than an Airy disk of the exposure beam. In other words, in exposing the photoresist, an exposure pattern having a line width of submicron size is formed by utilizing a nonlinear characteristic not in an ordinary steady state but in a transient response state.

In this case, the following combination is used as characteristics of the above described photoresist and the laser light source 16. FIG. 3 is a graph showing an absorbance (Abs) characteristic of the photoresist in each wave length (λ).

In FIG. 3, a laser light source characterized by a wavelength (for example, λ1) at which the absorbance (Abs) of photoresist is high, is normally used. However, in the present invention, a laser light source characterized by a wavelength (for example, λ2) at which the absorbance (Abs) of photoresist is low, is used.

That is, a laser light source characterized by a wavelength included in the resonance region shown by arrow R1 in FIG. 3, in which region the absorbance (Abs) of photoresist is high, is not used, but a laser light source characterized by a wavelength included in the non-resonance region shown by arrow R2, in which region the absorbance (Abs) of photoresist is low, is used.

As a result of an extensive investigation in this respect, the present inventors have found that a reaction time constant τ of a photosensitive material (photoresist and the like) is in a form of τ (I) which largely depends on the number of photons, that is, the intensity I and frequency of light incident on the photosensitive material, under conditions that the absorption cross section of the photosensitive material (photoresist and the like) in an excited state of photoreaction is large, and that the induced transition probability from the excited state is large and the spontaneous transition probability is small.

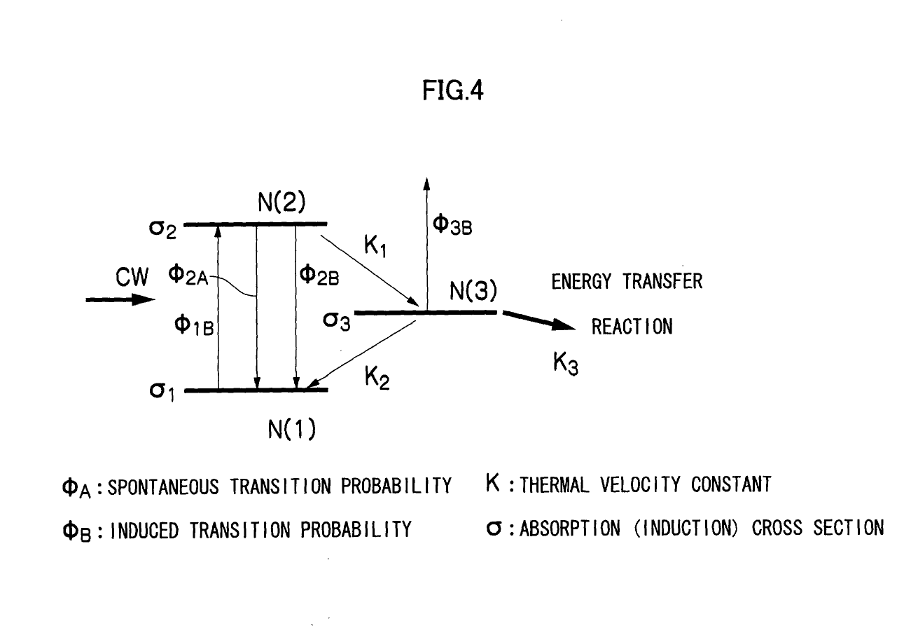

FIG. 4 is a conceptual figure showing an energy diagram of the photoresist. In FIG. 4, Φ_{A} is a spontaneous transition probability, Φ_{B} is an induced transition probability, K is a thermal velocity constant, and σ is an absorption (induction) cross section.

In the energy diagram shown in FIG. 4, atomic numbers of each level are defined as N(1), N(2) and N(3), respectively. In the present invention, a general reaction system in which energy transfer is caused via the energy level of level 3 is considered. In the present invention, a rate equation in a transient response range of photoresist is considered, because a coherent interaction of the photoresist is utilized and hence the heat mode reaction is considered to be sufficiently small in comparison with the photon mode reaction, and because exposure phenomena at the time of scanning an exposure beam is utilized instead of a reaction after a sufficient time has elapsed.

In the energy diagram, it is considered that the life time of the level 2 is sufficiently short in comparison with the life time of the level 3, with the result that the temporally variation of N(3) is very slow in comparison with the temporally variation of N(2). The reaction time constant of the photoresist which has been subjected to energy transfer from the level 3 is judged to be largely different in the order from the reaction time constant in the above described photon mode, so that only the photon mode reaction is considered to contribute to the temporally variation of N(3).

Then, the present inventors have found that in the exposure method according to the present invention, each of the above described parameters can be controlled and thereby the reaction rate of the photosensitive material can be intentionally handled, by controlling the irradiation time of exposure beam and the beam intensity. Noted that the irradiation time of the exposure beam is controlled on the basis of control of the scanning speed of substrate W.

Then, by solving the rate equation at the time of transient response based on the energy diagram of photoresist shown in FIG. 4, the present inventors have found that the reaction time constant τ is represented by the following formula (1), where ω is the frequency of light source, I is the intensity of irradiated light, and h is the Dirac constant.

$$τ = \frac{1}{\frac{{σ}_{1}}{{σ}_{3}} \frac{{Φ}_{1 B}}{{Φ}_{3 B}} {K}_{1} + \frac{I}{ℏ \cdot ω} {σ}_{2} {Φ}_{2 B} + {Φ}_{2 A} + {K}_{1}} \qquad formula ( 1 )$$

Here, the formula of τ=τ(0) represents the time lag from the time when light with a sufficiently low intensity is made incident on the photosensitive material (photoresist and the like) to the time when the photochemical reaction in the photosensitive material is started.

Further, τ (I) represents that the time lag from the time when light falls on the photosensitive material to the time when the photochemical reaction in the photosensitive material is started is a non-linear constant dependent upon the intensity of light. Noted that the reaction time constant of the photosensitive material (photoresist and the like) is constant during exposure by using ordinary incoherent light.

As a specific method, for example, under the control of irradiation time of the exposure beam, the reaction time constant τ (I:large) of the photoresist can be made small in a region of high incident light intensity I so that the reaction is made to progress at a high rate, and the reaction time constant τ (I:small) of the photoresist can be made large in a region of low incident light intensity I so that the reaction is made to progress at a low rate. Thereby, the photochemical reaction can be suppressed in the region of low light intensity within the light intensity distribution of the exposure beam, as a result of which it is possible to perform drawing with a line width thinner than the Airy disk of the exposure beam.

This makes it possible to simply form an exposure pattern having a line width of submicron size by using an inexpensive and simple device, as a result of which various fine projecting and recessed patterns can be formed.

Noted that the wavelength of exposure beam is preferably shifted from the resonance center of absorption wavelength within a range of ½ or less of the maximum light absorption ratio of the photoresist. This is because when the wavelength of exposure beam is set at the resonance center of absorption wavelength, the absorption cross section a σ1 in the level 1 in Formula (1) becomes large, and the induced transition probability Φ_{1B} from the level 1 to the level 2 in Formula (1) also becomes large. This is also because the thermal velocity constant (thermal spontaneous emission probability) K₁ from the level 2 to the level 3 in Formula (1) also becomes large, so that the dependence on the exposure beam intensity I is reduced and thereby the controllability of the reaction time constant t of photoresist is lowered.

However, in the case where the exposure time can be made extremely short, as in the case of pulse exposure, such requirement for shifting the wavelength is not necessary (the wavelength of exposure beam may be set in the resonance center region of absorption wavelength).

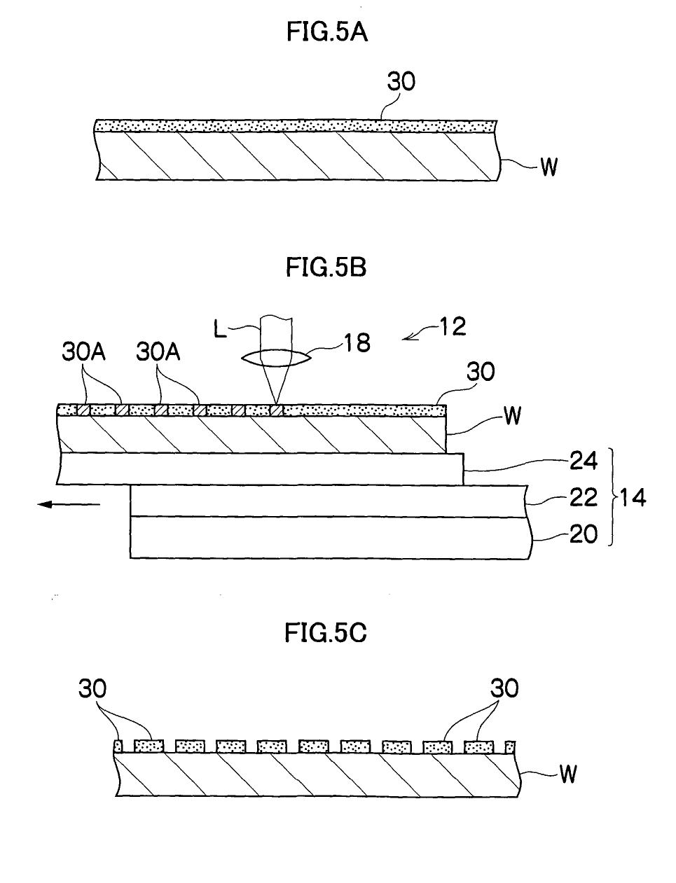

Next, the forming of a fine projecting and recessed pattern by an exposure process using the exposure device 10 shown in FIG. 1, and subsequent development process and the like, are described. FIG. 5A to FIG. 5C are schematic sectional views showing steps of processing the substrate W.

In FIG. 5A, a photoresist is applied to the surface of the substrate W (by the above described method, for example, the spin coating method), so that a photoresist layer 30 is formed. Then, the substrate W is subjected to a pre-baking process by a clean oven (not shown).

Then, as shown in FIG. 5B, the laser beam L which is emitted from the exposure light source 12 and condensed by the collimator lens 18 is irradiated on the surface of the substrate W, and as shown in the top view in FIG. 2, the substrate W on the substrate table 14 is scanned so that drawing (exposure) is performed over the surface of the substrate W by the condensed laser beam. In FIG. 5B, portions of a photoresist which have already been exposed are denoted by reference characters 30A, 30A, _ _ _ .

After the exposure process is completed, a projecting and recessed pattern having a fine cross-sectional shape as shown in FIG. 5C are formed on the surface of the substrate W, through a development process with a developer, then through a rinse process with pure water, and then through a post-baking process with a clean oven (not shown).

The substrate W having such cross-sectional shape can be used as it is as various kinds of optical elements, for example, as a diffraction grating. Further, such substrate W, on the surface of which the projecting and recessed pattern are regularly arranged, has an anti-reflection function due to an optical confinement phenomenon based on a quantum effect. Thus, the substrate W can preferably be used for applications, such as an optical element.

Further, a number of duplicates having the same cross-sectional shape can be manufactured through the steps as will be describe below, by using the substrate W having the above described cross-sectional shape as an original plate (mother).

Next, another embodiment of the method for forming a projecting and recessed pattern, and the method for manufacturing an optical element, according to the present invention, will be described in detail. The present embodiment is a method in which after a plurality of fine projecting and recessed patterns are formed on the surface of the substrate W, the same projecting and recessed patterns are further duplicated by using the plurality of fine projecting and recessed patterns, and thereby an optical element is manufactured.

That is, the present embodiment is a method for manufacturing an optical element, in which a stamper for transferring the fine projecting and recessed patterns is produced by using the plurality of fine projecting and recessed patterns formed on the surface of the completed substrate W (mother), and in which a plurality of fine projecting and recessed patterns substantially the same in the shape as the fine projecting and recessed patterns to be transferred are formed on the surface of a resin material by molding using the produced stamper, and thereby a plurality of optical elements are duplicated.

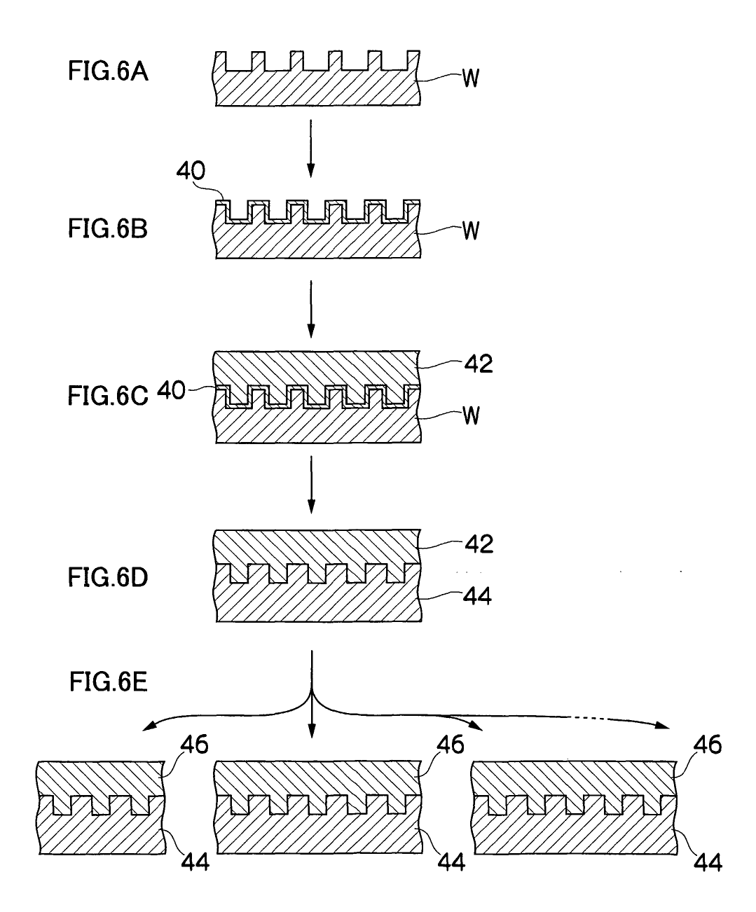

FIG. 6A to FIG. 6E are conceptual figures explaining steps of producing a stamper 46. In FIG. 6A, there is shown a cross-sectional shape of the substrate W which is a completed optical element.

First, as shown in FIG. 6B, a conductive layer 40 is formed on the whole surface of the substrate W. The conductive layer 40 serves as a contact layer when electroless plating is performed in the subsequent step. Therefore, the layer thickness is preferably minimized in terms of shape transfer precision in a range in which a predetermined resistance can be obtained.

As a material of the conductive layer 40, copper, silver and the like can be used, and as the layer thickness of the conductive layer 40, for example, a thickness of 0.1 μm can be adopted. As a method for forming the conductive layer 40, a vacuum deposition method, a sputtering method, an electroless plating method and the like can be used.

Subsequently, as shown in FIG. 6C, electroforming is performed, in which a nickel layer 42 is formed on the conductive layer 40 on the surface of the substrate W by electroless plating. The thickness of the nickel layer 42 may be an extent enough to prevent deformation in handling and the subsequent step for performing transfer of Ni mother 44. Noted that the nickel layer 42 formed by the electroless plating here, has a reversal shape of the pattern formed on the surface of the substrate W as a completed optical element, and serves as a reversed mother. The reversed mother 42 is peeled from the substrate W.

Subsequently, as shown in FIG. 6D, electroforming is performed, in which a nickel layer 44 is formed on the reversed mother 42 by electroless plating. The thickness of the nickel layer 44 may be an extent enough to prevent deformation in handling and the subsequent step for performing transfer of the stamper 46. Noted that the nickel layer 44 formed by the electroless plating here, has a shape the same as the pattern formed on the substrate W as a completed optical element, and serves as a Ni mother. After completion of electroforming, the Ni mother 44 is peeled from the reversed mother 42.

Subsequently, as shown in FIG. 6E, electroforming is performed, in which a nickel layer 46 is formed on the Ni mother 44 by electroless plating. The nickel layer 46 is used as a stamper. The thickness of the nickel layer 46 needs to be an extent enough to withstand the use condition as the stamper. Noted that the nickel layer 46 formed by the electroless plating here, has a reversal shape of the pattern formed on the surface of the substrate W as a completed optical element.

As shown in FIG. 6E, in the present steps, a plurality of stampers 46 can be reproduced from one Ni mother 44. Therefore, this is advantageous in the case where a number of sheets of optical elements are manufactured at the same time, for example, by multistage hot press processing. After completion of electroforming, the nickel layer (stamper) 46 is peeled from the Ni mother 44.

Various kinds of known molding method can be used as the manufacturing method for duplicating optical elements, because a plurality of fine projecting and recessed patterns substantially the same in the shape as the projecting and recessed patterns of the optical element (mother) completed on the surface of the resin material are formed by molding using the stamper 46. For example, it is possible to use an injection molding method, a hot press molding method, a transfer molding method for UV curing resin, a transfer molding method for EB curing resin, and a solution casting drying curing molding method, and the like. In the various molding methods, it is also possible to apply not only the methods using the plate-shaped stamper, but also a roll forming method using a roll-like stamper (for example, the solution casting drying curing molding method).

As described above, embodiments of the exposure method, the method for forming a projecting and recessed pattern, and the method for manufacturing an optical element, according to the present invention, are explained. However, the present invention is not limited to the above described embodiments, but various kinds of modes can be taken as the embodiment according to the present invention.

For example, according to the present embodiment, in FIG. 2, the X-axis moving stage 22 and the Y-axis moving stage 24 are driven so that substantially the whole surface of the substrate W is exposed by the laser beam spot P. However, a configuration can also be employed, in which the substrate W is not moved but the laser beam is scanned by for example a polygon mirror, so that substantially the whole surface of the substrate is exposed.

Further, in manufacturing the optical element, as shown in FIG. 6E, the reversal shape of the pattern formed on the surface of the substrate W as a completed optical element is used as the stamper 46. However, the Ni mother 44 having the same shape as the pattern formed on the surface of the substrate W as a completed optical element can also be used as the stamper. In this case, the surface of the resin material formed by molding has a reversal shape of the pattern formed on the surface of the substrate W. This is because there is also a case where even such resin material effectively functions as an optical element.

Further, in the above described embodiments, the stamper is described as a plate-shaped member, but a roll-like member may also be used as the stamper. In this case, as a method for manufacturing the roll-like stamper, it is also possible to employ a configuration in which a sheet-like Ni mother 44 is wound around a columnar body and thereby a reversed mold is formed by electroforming, and a configuration in which a sheet-like Ni mother 44 is deformed into a cylindrical shape so that the surface of the fine projecting and recessed pattern is positioned on the inner periphery side and then a reversed mold is formed by electroforming.

Further, for example, it is also possible to employ a configuration in which a columnar body or a cylindrical body is used as the substrate W, and in which a plurality of fine projecting and recessed patterns are formed on the surface of the columnar body or on the inner peripheral surface of the cylindrical body, so as to be used as a mother to form a roll-like stamper by electroforming.

Further, it is also possible to employ a configuration in which a columnar body or a cylindrical body is used as the substrate W, in which a plurality of fine projecting and recessed patterns are formed on the surface of the columnar body or the inner peripheral surface of the cylindrical body, and in which the surface of the fine projecting and recessed patterns is subjected to electroforming processing with a predetermined thickness so as to have a predetermined hardness, so that the columnar body or the cylindrical body is used as it is as a roll-like stamper.

Further, the ratio of the projecting portion to the recessed portion in the cross-sectional shape of the projecting and recessed pattern as shown in FIG. 6A to FIG. 6E, may also be made different from the ratio of 1 to 1 as shown in the figures, by controlling exposure conditions.

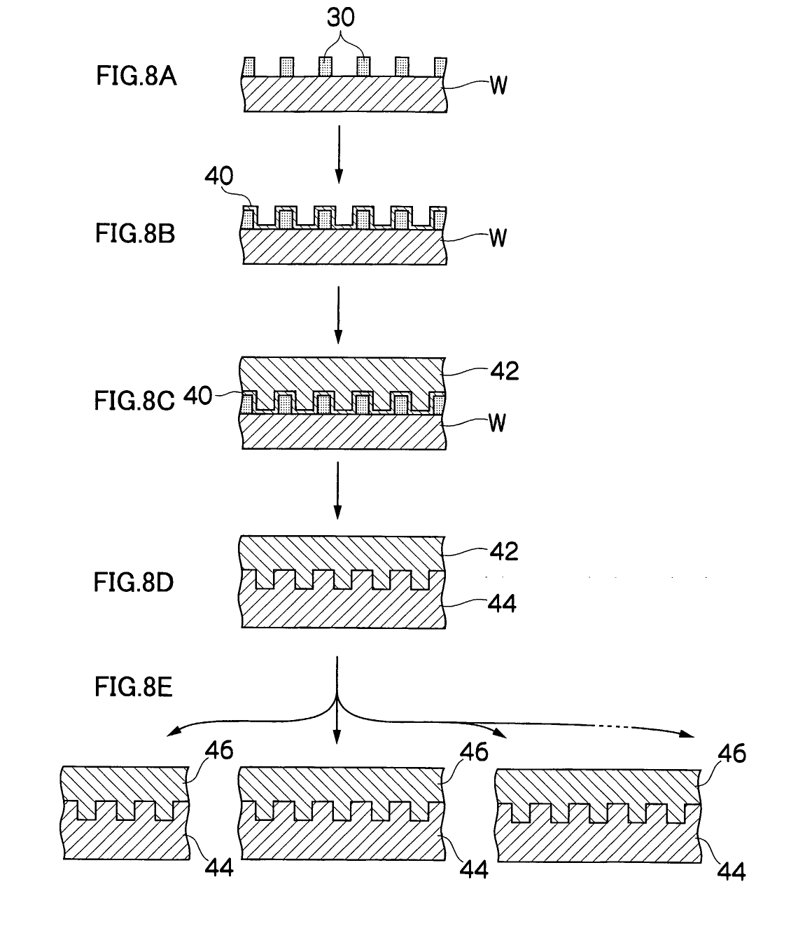

Also, the steps of producing a stamper for transferring the fine projecting and recessed patterns are not limited to the above described embodiments. FIG. 8A to FIG. 8E are conceptual figures explaining other steps of producing a stamper. FIG. 8A to FIG. 8E correspond to FIG. 6A to FIG. 6E described above.

In FIG. 8A, there is shown a cross-sectional shape of the substrate W which is a completed optical element. In the present embodiment, the plurality of fine projecting and recessed patterns of the photoresist 30 which are the same shape as a cross-sectional shape in FIG. 5C are used, in stead of the plurality of fine projecting and recessed patterns formed on the surface of the substrate W in FIG. 6A.

That is, the present embodiment is a method for manufacturing an optical element, in which a stamper for transferring the fine projecting and recessed patterns is produced by using the plurality of fine projecting and recessed patterns of the photoresist 30 formed on the surface of the substrate, and in which a plurality of fine projecting and recessed patterns substantially the same in the shape as the fine projecting and recessed patterns to be transferred are formed on the surface of a resin material by molding using the produced stamper, and thereby a plurality of optical elements are duplicated.

First, as shown in FIG. 8B, a conductive layer 40 is formed on the whole surface of the substrate W. The present steps are substantially the same as FIG. 6B. The conductive layer 40 serves as a contact layer when electroless plating is performed in the subsequent step.

Subsequently, as shown in FIG. 8C, electroforming is performed, in which a nickel layer 42 is formed on the conductive layer 40 on the surface of the substrate W by electroless plating. The present steps are substantially the same as FIG. 6C. The reversed mother 42 is peeled from the substrate W.

Subsequently, as shown in FIG. 8D, electroforming is performed, in which a nickel layer 44 is formed on the reversed mother 42 by electroless plating. The present steps are substantially the same as FIG. 6D. After completion of electroforming, the Ni mother 44 is peeled from the reversed mother 42.

Subsequently, as shown in FIG. 8E, electroforming is performed, in which a nickel layer 46 is formed on the Ni mother 44 by electroless plating. The nickel layer 46 is used as a stamper. The present steps are substantially the same as FIG. 6E.

As shown in FIG. 8E, in the present steps, a plurality of stampers 46 can be reproduced from one Ni mother 44. The present steps of molding by using the stamper 46 are same as FIG. 6E.

### EXAMPLE

The substrate W was exposed by using the exposure device 10 shown in FIG. 1, and a plurality of fine projecting and recessed patterns were formed on the surface of the substrate W.

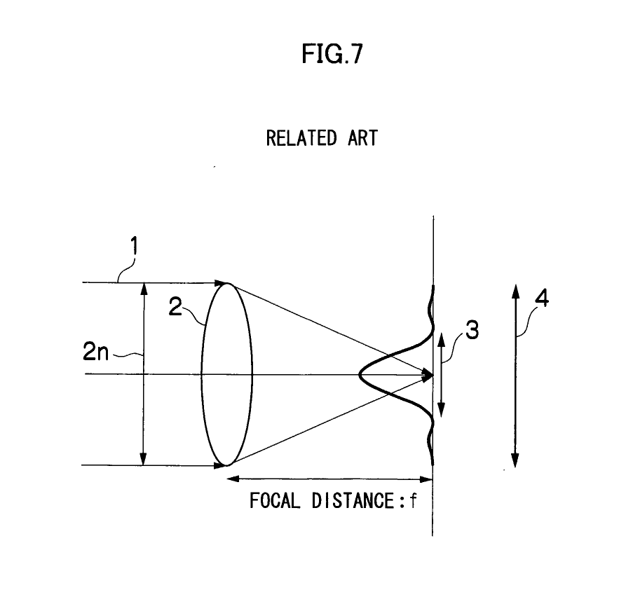

A Nd:YAG laser (SHG wavelength of 532 nm) was used as the laser light source 16 of the exposure light source 12. Prior to exposure, the diameter of the primary Airy disk 3 (see FIG. 7) and the diameter of the secondary Airy disk of the laser beam emitted from the laser light source 16 and condensed by the collimator lens 18, were measured.

For measurement, a photoresist was applied and formed on the surface of the substrate W, on which surface the laser beam was irradiated in accordance with a recommended condition of the photoresist. After development, the profile of the irradiated portion was measured by AFM. Further, the laser beam for irradiation was directly measured by a laser beam profiler (made by Gentec Corp., product name: Beam Map).

As a result, the diameter of the primary Airy disk 3 was 722 nm in the focus position, and the diameter of the secondary Airy disk was 1.2 μm.

As the substrate W, a substrate made of soda lime glass (float glass) having thickness of 5 mm was used. After the substrate W was washed and dried, a photoresist (g-line positive photoresist) was applied and formed on the surface of the substrate W so as to have layer thickness of 2 μm after drying. As the photoresist, a product made by Arch Corp. (product name: OIR-907) was used.

In exposure processing by use of the exposure device 10, exposure was performed while the beam intensity and the scanning rate (in practice, moving velocity of the substrate W) of laser beam was controlled, so that exposure could be performed with the reaction time constant of the photoresist being locally controlled. Specifically, the beam intensity of the laser beam was set to be I=535 μW, and the moving velocity of the substrate W in the X-axis direction was set to be V=500 μm/s. The line scan width in the Y-axis direction of the substrate W was set to 1 μm.

After exposure, a development processing by a developer, a rinse processing by pure water, and a post baking processing were performed. Then, the formed pattern was measured, and it was confirmed that the pattern had a pattern line width of about 700 nm and a pattern depth of about 2 μm (corresponding to layer thickness of the photoresist).

Next, as a comparison example, exposure was performed without locally controlling the reaction time constant of the photoresist. Specifically, the beam intensity of the laser beam was set to be I=45 μW, and the moving velocity of the substrate W in the X-axis direction was set to be V=200 μm/s. The line scan width in the Y-axis direction of the substrate W is set to 1 μm.

After exposure, the development processing by the developer, the rinse processing by pure water, and the post baking processing were performed. Then, the formed pattern was measured, and it was confirmed that the pattern had a pattern line width of about 750 nm and a pattern depth of about 100 nm.

Further, as another comparison example, exposure was performed without locally controlling the reaction time constant of the photoresist. Specifically, the beam intensity of the laser beam was set to be I=535 μW, and the moving velocity of the substrate W in the X-axis direction was set to be V=100 μm/s. The line scan width in the Y-axis direction of the substrate W was set to 1 μm.

After exposure, the development processing by the developer, the rinse processing by pure water, and the post baking processing were performed. Then, the formed pattern was measured, and it was confirmed that the whole surface was exposed with no pattern formed.

1. An exposure method suitable for manufacturing an element having a projecting and recessed pattern, comprising:
irradiating a laser beam on a layer of a photosensitive material having a predetermined thickness formed on a surface of a substrate, while controlling beam intensity and beam scanning rate of the laser beam,
whereby exposure is performed by locally controlling a reaction time constant of the photosensitive material with beaming the laser beam.

2. The exposure method according to claim 1, wherein a desired exposure width is smaller than a diameter of an Airy disk of the laser beam.

3. The exposure method according to claim 1, wherein the laser beam is temporally and spatially coherent light.

4. The exposure method according to claim 2, wherein the laser beam is temporally and spatially coherent light.

5. An exposure method suitable for manufacturing an element having a projecting and recessed pattern, comprising:
irradiating a laser beam in pulse state on a layer of a photosensitive material having a predetermined thickness formed on a surface of a substrate, while controlling beam intensity and pulse width of the laser beam,
whereby exposure is performed by locally controlling a reaction time constant of the photosensitive material with beaming the laser beam in pulse state.

6. The exposure method according to claim 5, wherein a desired exposure width is smaller than a diameter of an Airy disk of the laser beam.

7. The exposure method according to claim 5, wherein the laser beam is temporally and spatially coherent light.

8. The exposure method according to claim 6, wherein the laser beam is temporally and spatially coherent light.

9. A method for forming projecting and recessed pattern, comprising:
forming a layer of a photosensitive material having a predetermined thickness on a surface of a substrate;
performing exposure in which a reaction time constant of the photosensitive material is locally controlled by controlling beam intensity and beam scanning rate of the laser beam, while beaming a laser beam on the layer of the photosensitive material;
performing development of the layer of the photosensitive material after the exposure; and
forming a plurality of fine projecting and recessed patterns on the layer of the photosensitive material.

10. The method for forming projecting and recessed pattern according to claim 9, wherein the height of the projecting and recessed pattern is set to 0.1 to 100 μm.

11. The method for forming projecting and recessed pattern according to claim 9, wherein the substrate is a columnar body or a cylindrical body.

12. A method for manufacturing an optical element by using the method for forming projecting and recessed pattern according to claim 9, comprising:
producing a stamper to which the surface shape of the plurality of projecting and recessed patterns is transferred by using the plurality of projecting and recessed patterns formed on the surface of the substrate; and
duplicating a plurality of projecting and recessed patterns substantially the same in shape as the plurality of projecting and recessed patterns, on the surface of a resin material by molding using the stamper.

13. The method for forming projecting and recessed pattern according to claim 10, wherein the substrate is a columnar body or a cylindrical body.

14. A method for manufacturing an optical element by using the method for forming projecting and recessed pattern according to claim 10, comprising:
producing a stamper to which the surface shape of the plurality of projecting and recessed patterns is transferred by using the plurality of projecting and recessed patterns formed on the surface of the substrate; and
duplicating a plurality of projecting and recessed patterns substantially the same in shape as the plurality of projecting and recessed patterns, on the surface of a resin material by molding using the stamper.

15. A method for manufacturing an optical element by using the method for forming projecting and recessed pattern according to claim 11, comprising:
producing a stamper to which the surface shape of the plurality of projecting and recessed patterns is transferred by using the plurality of projecting and recessed patterns formed on the surface of the substrate; and
duplicating a plurality of projecting and recessed patterns substantially the same in shape as the plurality of projecting and recessed patterns, on the surface of a resin material by molding using the stamper.

16. A method for manufacturing an optical element by using the method for forming projecting and recessed pattern according to claim 13, comprising:
producing a stamper to which the surface shape of the plurality of projecting and recessed patterns is transferred by using the plurality of projecting and recessed patterns formed on the surface of the substrate; and
duplicating a plurality of projecting and recessed patterns substantially the same in shape as the plurality of projecting and recessed patterns, on the surface of a resin material by molding using the stamper.
